(19) United States
(12) Patent Application Publication
(10) Pub. No.: US 2009/0208668 A1
(43) Pub. Date: Aug. 20, 2009

(54) FORMATION OF CLEAN INTERFACIAL THIN FILM SOLAR CELLS

(76) Inventors: SOO YOUNG CHOI, Fremont, CA (US); John M. White, Hayward, CA (US)

Correspondence Address: SHIRLEY L. CHURCH, ESQ., P.O. BOX 81146, SAN DIEGO, CA, 92138, US

(21) Appl. No.: 12/033,240

(22) Filed: Feb. 19, 2008

(51) Int. Cl. C23C 16/44

(52) U.S. Cl. 427/569; 118/715

(57) ABSTRACT

A “three” chamber design multi-chamber cluster processing system which is used in the fabrication of a solar cell-comprising substrate. The processing system includes at least one PECVD processing chamber configured to deposit a p-doped layer, at least three PECVD processing chambers configured to deposit an i-layer, and at least one PECVD processing chamber configured to deposit an n-doped layer. The processing system also includes at least one central substrate transferring chamber which is typically located substantially equidistant from each of the PECVD processing chambers, and a transfer robot present in the central transferring chamber which is capable of paired transfer of substrates. An apparatus which provides a source of fluorine-comprising reactive species is in communication with each of said PECVD processing chambers.

### BACKGROUND OF THE INVENTION

1. Field of the Invention

The present invention pertains to a method of forming thin film solar cells. In addition, the present invention pertains to an efficient method of providing a clean interface between each of the various layers deposited during formation of a solar cell.

2. Brief Description of the Background Art

This section describes background subject matter related to the disclosed embodiments of the present invention. There is no intention, either express or implied, that the background art discussed in this section legally constitutes prior art.

Solar cell technology, a desirable clean energy source, has not been competitive with conventional energy sources due in large part to the cost of fabrication of the solar cell arrays. The conversion efficiency, CE, of a solar cell is a measure of the amount of absorbed light that is converted to electrical power. The best conversion efficiency achieved using silicon-containing solar cells has been with essentially single crystal silicon. Originally, the typical conversion efficiencies achieved were in a range from about of 15-20%. Recently conversion efficiencies in the range of up to about 40% when solar cell design and optical design are integrated to advantage. However, this higher conversion efficiency comes with the disadvantage of increased weight and a more complicated solar cell structural design. Single crystal silicon is expensive to produce on a large scale. Thin film solar cells can be fabricated on large substrate surfaces (more than one meter square, for example) using semiconductor manufacturing techniques, which provides a reduced cost of production. The thin film solar cells are typically fabricated using microcrystalline silicon in combination with various dopants. Conversion efficiencies for the thin film solar cells have recently reached efficiencies in the 15% range. Conversion efficiency is improved by using a textured cell surface alone or in combination with an antireflective coating, to reduce reflection away from the surface of the cell, and to thereby improve collection of sunlight.

Thin film solar cells are frequently deposited on glass, but may be deposited on other materials as well, such as flexible plastics. Thin film solar cells generally consist of a at least one cell which comprises a p-doped layer, an intrinsic layer, and an n-doped layer (a PIN structure). More efficient solar cells are produced by constructing tandem solar cell arrays in which more than one PIN structure is deposited in a “stacked” manner, to form a solar cell matrix. The multiple layers of the thin film solar cells are commonly deposited using chemical vapor deposition (CVD) or plasma-enhanced chemical vapor deposition (PECVD) upon the glass or plastic substrate. These deposition techniques generally tend to produce a microcrystalline structure having a crystal size in the range of a few hundred Angstroms. Microcrystalline silicon (mc-Si) has lower carrier mobility than single crystal silicon, due to the many dangling bonds which can serve as recombination centers for the electron-hole pairs generated by captured photons, and this reduces the solar cell efficiency.

Mc-Si solar cell efficiencies are typically increased by the addition of dopants which lead to increased electric field within the device. Mc-Si tandem solar cells formed by stacking cells having different bandgaps allow each cell in the tandem solar cell to absorb 18 light over a different wavelength range, leading to more power generation.

It is known that one factor which contributes to a higher conversion efficiency is a sharp interface between the p-doped, intrinsic, and n-doped layers. One main problem in obtaining a sharp interface between layers has been the contamination of the intrinsic (i) layer with the p dopant at the interface between a p-doped layer and an intrinsic layer. This results in a gradual transition in the concentration of the p dopant from the p-layer to the i-layer, rather than a sharp interface. This weakens the electric field in the i-layer, this electric field being necessary to generate a current out of the photo-generated carriers, and results in reduced conversion efficiency.

A number of processing schemes have been devised for fabrication of the multi-layered solar cell structures. In the beginning, each chemically different layer of the cell structure was deposited in a separate processing chamber, thus preventing the dopants used for one layer, such as the p-doped layer, from contaminating another layer, such as the intrinsic layer. However, this limited the throughput in terms of solar cell substrates produced per hour, and required the use of an increased number of chambers to generate the substrates. Efforts were made to find a way to prevent the contamination while fabricating a solar cell in a single chamber, or to limit contamination by producing the P layer in one chamber and the I and N layers in a second chamber.

U.S. Pat. No. 5,180,434, DiDio et al., Mar. 11, 1991, “Interfacial Plasma Bars for Photovoltaic Deposition Apparatus”, describes a method of fabricating a p-i-n structure where “gas gates” of a flow of inert gas are used to prevent boron present in a chamber that is used to form the p-doped layer from entering the chamber where the intrinsic layer is subsequently formed.

Lloret et al., in an article entitled “Hydrogenated Amorphous Silicon p-Doping with Diborane, Trimethylboron, and Trimethylgallium”, Applied Physics A 55, pp. 573-581 (1992), describe the formation of a p-i-n structure. They provide a comparison between using diborane, trimethylboron (TMB), or trimethylgallium to form a p-type amorphous silicon layer. Lloret et al. reach the conclusion that TMB is much more thermally stable than diborane, and therefore recommend the use of TMB in a cold wall reactor environment, as a means of reducing contamination of a subsequently deposited i-layer. The authors also mention that the state of the art efficiency (CE) for CVD solar cells is 7%.

EP 631329 A1, Kase et al., Dec. 28, 1994, “Amorphous silicon solar cell for integrated solar cells or photo sensors production obtained by forming amorphous silicon layer with p-i-n junction and back electrode layer on insulating transparent substrate with transparent electrode layer”, discloses forming an amorphous silicon-containing solar cell using a reactive gas mixture containing silane, methane, diborane and some trimethylboron, to deposit a p-type amorphous silicon carbide layer. They do not address the boron contamination problem.

U.S. Pat. No. 6,399,873, Sano et al., Feb. 25, 1999, “Stacked Photovoltaic Device”, disclose a stacked device of three solar cells, each constituting a p-doped layer, an intrinsic layer, and an n-doped layer. An amorphous silicon is used as the intrinsic layer in the first cell of the stack, and microcrystalline silicon is used as the intrinsic layer in the second and third cells of the stack. Diborane is used as the boron source for p-layer doping.

U.S. Pat. No. 6,700,057, Yasuno, Jun. 25, 2002, “Photovoltaic Device”, discloses a photovoltaic device of three stacked solar cells, each having non-single-crystalline silicon layers. The photovoltaic device is an n-i-p structure, where the n-doped, intrinsic, and p-doped layers are all formed in series in a process chamber. Since the n-doped layer, which is a phosphorus-doped amorphous silicon, does not tend to contaminate the process chamber, the chamber is conveniently cleaned after the deposition of the boron-doped p-layer.

The interface between the p-doped layer and an i-doped layer is the major semiconductor junction that is responsible for the electric field that generates the current from the photo-generated carriers. Since photo-generated holes have lower mobility than photo-generated electrons, holes generated close to a p-doped layer can be more effectively collected to contribute to the current of the solar cell. Light usually strikes the thin film silicon solar cells from the p-doped side such that most photo-generated electron-holes are generated near the p/i interface and can be more effectively collected. For this reason, a p-i-n solar cell is preferred to an n-i-p solar cell.

Ballutaud et al., in an article titled “Reduction of the Boron Cross-Contamination for Plasma Deposition of p-i-n devices in a Single-Chamber Large Area Radio-Frequency Reactor”, Thin Solid Films, Vol. 468 (2004), pages 222-225, disclose a method of avoiding the contamination of the interface between a p-doped layer and an intrinsic layer by introducing a gas able to react with the doping agent on the surface of the p-doped layer, after forming the p-layer and prior to the formation of the i-layer. The gases used were said to “fix the doping agent species”, and include ammonia, water, methanol, isopropanol and other alcohols, as well as hydrazine, or other volatile organic amines. The authors conclude that an ammonia flush creates boron-nitrogen molecular complexes which fixes the boron in the p-layer, preventing it from migrating into the intrinsic layer.

Despite problems with contamination of layer composition which has occurred when multiple layers of material having different chemical compositions are deposited in the same processing chamber, the use of separate processing chambers for deposition of individual solar cell layers has been generally rejected. This has been based on the increased number of processing chambers which may be required and on the increased processing time required when separate processing chambers are used for each layer in a sequence of layers. The substrate has to be transferred from chamber to chamber during the fabrication process.

The solar cell industry is in its infancy, in part due to the cost of producing a system which provides sufficient power generation to justify the cost of a solar cell to a consumer. The cost per power generation, $/Watt, must be reduced by increasing the CE, and by making efficient use of the apparatus used to fabricate the solar cells. A fabrication method is needed which provides higher throughput, thereby driving down the fabrication costs. The CE of the solar cell can be improved by the design of various solar cell structures including various combinations of active layers and by the use of better performing materials in the layers. Simultaneously, the apparatus used to fabricate the solar cells must be improved to provide advantageous throughput rates.

### BRIEF DESCRIPTION OF THE DRAWINGS

FIG. 1 shows a PECVD processing chamber of the kind which can be used to produce solar cells using semiconductor processing techniques.

FIG. 2 shows a comparative “single” chamber design, multi-chamber PECVD cluster processing system 240, which includes a load lock docking chamber 242 and seven film/layer-depositing chambers, each of which is capable of depositing a p-doped layer, an i-layer, and an n-doped layer. The processing chambers 250 are capable of depositing a-silicon-containing layers, while the processing chambers 252 are capable of depositing mc-silicon-containing layers or amorphous (a-silicon) layers. This multi-chambered cluster processing system is referred to as a “single” chamber process apparatus, because a p-doped layer, an i-doped layer, and an n-doped layer may be deposited in any of the processing chambers 250, 252, and combinations thereof. The processing chambers 252 which are capable of depositing an mc-silicon-containing layer or an amorphous, a-silicon-containing layer provide processing flexibility. The cluster processing system includes a load lock docking chamber 242, and seven film deposition chambers of the kind shown in FIG. 1, arranged around a central transfer chamber 244 which contains a central substrate transfer robot 246.

FIG. 3A shows a comparative “two” chamber design of a multi-chambered PECVD cluster processing system 300, which includes a load lock docking chamber 302 and five film/layer-depositing chambers. This cluster processing system is referred to as a “two” chamber process apparatus, because a p-doped layer may be deposited in a first chamber 304, while an i-doped layer and a n-doped layer may be deposited in any of the second processing chambers 306a-306d. Film forming chamber 304 is capable of depositing a p-doped layer, and the other four chambers 306a, 306b, 306c, and 306d are capable of depositing an i-layer or an n-doped layer. The five film deposition chambers of the kind shown in FIG. 1, are arranged around a central transfer chamber 309 which contains a central substrate transfer robot 308.

FIG. 3B shows a comparative “two” chamber PECVD cluster processing system 350, which is similar to the two chamber PECVD cluster processing system 300 shown in FIG. 3A, except that there are seven film/layer depositing chambers. One film forming chamber 354 capable of depositing a p-doped layer, and six other film/layer depositing chambers 356a-356f, capable of depositing an i-layer and an n-doped layer. The cluster processing system includes a load lock docking chamber 352, and seven film deposition chambers of the kind shown in FIG. 1, arranged around a transfer chamber 359 which contains a robot 358.

FIG. 4A shows a “three” chamber design of a multi-chamber PECVD cluster processing system 400 of the kind which may be used to practice embodiments of the present invention. The three chamber processing system includes a load lock docking chamber 402 and five film/layer-depositing chambers. One film-forming chamber 404 is capable of depositing a p-doped layer; three film-forming chambers 406a-406c, are capable of depositing an i-layer; and one film-forming chamber 407 is capable of depositing an n-doped layer. This cluster processing system is referred to as a “three” chamber process apparatus because each different kind of layer is deposited in a separate chamber. The cluster processing system includes a load lock docking chamber 402, and five film deposition chambers of the kind shown in FIG. 1, arranged around a transfer chamber 409 which contains a robot 408.

FIG. 4B shows a “three” chamber design PECVD cluster processing system 450, which is similar to the “three” chamber design PECVD cluster processing system 400 shown in FIG. 4A, except that there are seven film/layer depositing chambers. One film-forming chamber 454 capable of depositing a p-doped layer; five film/layer depositing chambers 456a-456e, capable of depositing an i-layer; and one film/forming chamber 457 capable of depositing an n-doped layer. The cluster processing system includes a load lock docking chamber 452, and seven film deposition chambers of the kind shown in FIG. 1, arranged around a transfer chamber 459 which contains a robot 458.

### SUMMARY

It is possible to form thin film solar cells of various structures which achieve collection efficiencies in the range of 6% to 11%, when there is essentially no contamination at the interfaces between the various layers of p-type, i-type, and n-type materials. This can be achieved when the fabrication process makes use of dedicated processing chambers for each different type of material deposited. It has been generally assumed that the use of dedicated process chambers to deposit each layer of a PIN solar cell, for example, is not competitive economically, largely because of additional transfer operations required between chambers, thus increasing the production time required.

We have empirically determined that due to the importance of the cleaning and seasoning of the processing chambers, and the amount of cleaning and seasoning time required to ensure that dopant interdiffusion between layers is avoided, as well as particulate formation, a system comprising dedicated processing chambers is economically competitive. Empirical data has established that the final substrate throughput per hour is somewhat better for a “three” chamber design cluster multi-chambered processing system than for a “two” chamber design cluster multi-chambered processing system, for a single junction PIN solar cell. One skilled in the art will be able to determine, as we have that for solar cells with multiple junctions, the results are the same in terms of substrate throughput per hour. The advantage of the “three” chamber design is that a the cost of chamber cleaning gas is reduced by about 20% and there is less risk that the quality of the interfaces between layers may be compromised by a processing error.

We have concluded, after review of all of our experimental data, and consideration of the implications of that data, that a “three” chamber design of a multi-chambered cluster processing system, used in combination with a specialty robotic handling system is economically advantageous over a “single” chamber design and slightly cheaper to operate than a “two” chamber design.

A multi-chambered cluster processing system is advantageously designed so that a central substrate transferring robot having “dual arm” capability or better is used to transfer substrates during processing. The use of an advantageous robot design, such as one which provides “paired” transfer of substrates (a robot having a dual set of arms) is very important. This reduces the number of times the process chamber opening (typically a slit valve”) needs to be opened and closed, and saves time in substrate handling. Typically, the substrate transferring robot is capable of at least 15 paired transfers of substrates per hour. Further, the mechanical throughput rate of substrates per hour within the processing system is at least 20. Auxiliary apparatus in the processing chambers is designed to cooperate with the robotic handling system.

The relative number of p-chambers, i-chambers and n-chambers is determined by the relative length of the required processing time in each kind of chamber.

The conclusion, based on our empirical data and analysis of the possibilities, is that the previous assumptions which have been made, that a “three” chamber design processing system is not competitive with a “two” chamber design, for example, were incorrect. When process chamber cleaning and seasoning operations are taken into account, a “three” chamber design is competitive with a “two” chamber design, as illustrated in the Table provided in the Detailed Description. In particular, with reference to the “three” chamber design, an average total clean and seasoning time period per substrate, considering the cleaning and seasoning of all PECVD chambers, is about 55 seconds or less.

### DETAILED DESCRIPTION OF EXEMPLARY EMBODIMENTS

As a preface to the detailed description presented below, it should be noted that, as used in this specification and the appended claims, the singular forms “a”, “an”, and “the” include plural referents, unless the context clearly dictates otherwise.

When the word “about” is used herein, this is intended to mean that the nominal value presented is precise within ±10%.

It is possible to form thin film solar cells of various structures which achieve collection efficiencies in the range of 6% to II %, when there is essentially no contamination at the interfaces between the various layers of p-type, i-type, and n-type materials. This can be achieved when the fabrication process makes use of dedicated processing chambers for each different kind of material. It has been generally assumed that the use of dedicated process chambers was not competitive economically, because of the initial cost of purchasing more processing chambers, and because of the additional processing time required.

The discovery that it is possible to fabricate solar cell structures using separate processing chambers for the formation of chemically different layers, which prevents contamination of interfaces between the layers, and still maintain an economically competitive product has been established. The apparatus used to generate the empirical data was apparatus of the kind typically used to produce large scale flat panel displays, and was an AKT 60K PECVD System available from Applied Materials, Inc., AKT Division.

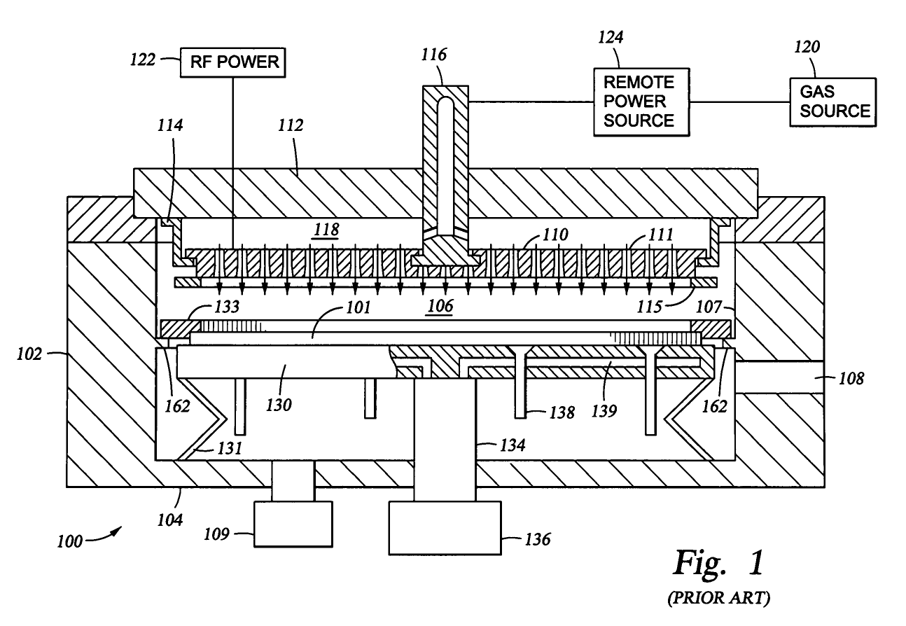

FIG. 1 shows a known, typical processing chamber 100 of the kind which is has been used to produce flat panel displays and which can also be used to produce solar cell structures. The processing chamber typically deposits PECVD layers on a solar cell substrate. Such processing chambers are typically large in size, capable of processing substrates having a surface area of at least 1,000,000 mm², by way of example and not by way of limitation.

The example plasma enhanced chemical vapor deposition (PECVD) processes described herein were carried out in a parallel plate processing chamber, such as the one available from AKT™, a division of Applied Materials, Inc., Santa Clara, Calif. FIG. 1 is a schematic cross-section of one embodiment of a PECVD chamber 100 in which a portion of the method of the present invention may be carried out. It is contemplated that other similar deposition chambers which are known in the art may be used in embodiments of the invention.

The example processing chamber 100 generally includes walls 102, a bottom 104, a showerhead 110, and substrate support 130 which define a process volume 106. The process volume 106 is accessed through a “slit” valve 108 such that a substrate, such as substrate 101, may be transferred into and out of the chamber 100. The substrate support 130, which acts as a susceptor/electrode, supports the substrate 101. The substrate support 130 is coupled to a lift column 134, which is coupled to a lift system 136 so that substrate support 130 can be raised and lowered within the interior of process chamber 100. The lift column 134 additionally provides a conduit for electrical and thermocouple leads (not shown) between the support assembly 130 and other components (not shown) of the system 100. A shadow form 133 may optionally be used in conjunction with the substrate 100. Lift pins 138 are moveably disposed through the substrate support 130 to lift a substrate 101 above the substrate support 130, so that substrate 101 can be easily removed from process chamber 100 by a robot (not shown). The substrate support assembly 130 may also include heating and/or cooling elements 139 to the maintain substrate support assembly 130 at a desired temperature. The substrate support 130 may also include grounding straps 131 to provide RF grounding at the periphery of the support. Examples of grounding straps are disclosed in U.S. Pat. No. 6,024,044 issued on Feb. 15, 2000 to Law et al. and U.S. patent application Ser. No. 11/613,934 filed on Dec. 20, 2006 to Park et al., which are both incorporated by reference in their entirety to the extent not inconsistent with the present disclosure.

The showerhead 110, sometimes called a diffuser plate or a gas distribution plate, is coupled to a backing plate 112 at its periphery by a suspension 114, sometimes called a hanger plate. The showerhead 110 and the suspension 114 may alternatively comprise a single unitary member. The suspension 114 maintains the showerhead 110 and the backing plate in a spaced-apart relation, thereby defining a plenum 118. The showerhead 110 may also be coupled to the backing plate by one or more center supports 116 to help prevent sag and/or control the curvature of the showerhead 110. The plenum 118 provides for a uniform distribution of the gases across the width of the showerhead. The showerhead 110 is provided with a plurality of gas passages 111 to allow a predetermined distribution of film-forming precursor gases (not shown) to pass through the showerhead. In one embodiment, the showerhead 110 provides for a uniform distribution of gas flow from the plenum 118 to the substrate 101. A gas distribution shield 115 may be provided around the edges of the showerhead, to reduce gas flow around the periphery of showerhead 110, to prevent edge build up of film on the substrate 101.

A gas source 120 is in communication with the backing plate 112 to provide gas through the backing plate 112 and through the showerhead 110 to the upper surface (not shown) of substrate 101. A vacuum pump 109 is in communication with chamber 100 to control process volume 106 at a desired pressure. An RF power source 122 is coupled to the backing plate 112 and/or to the showerhead 110 to provide a RF power to the showerhead in a manner such that the showerhead 110 acts as a first electrode, while the substrate support 130, which is grounded, acts as a second electrode, so that an electric field is created between the showerhead 110 and the substrate support 130. This combination of electrodes permits the generation of a plasma (not shown) in the process volume 106, where the plasma is created from the gases which flow from the showerhead 110. Various RF power frequencies may be used, such as a frequency between about 0.3 MHZ and about 200 MHZ. In one commonly used embodiment, an RF power frequency of 13.56 MHZ is used. Examples of showerheads are disclosed in U.S. Pat. No. 6,477,980 issued on Nov. 17, 2006 to Choi et al., and U.S. Publication 2006/0060138 published on Mar. 23, 2006 to Keller et al, which are all incorporated by reference in their entirety to the extent not inconsistent with the present disclosure.

A remote plasma source 124, such as an inductively coupled remote plasma source, may also be in communication with the plenum 118, so that remotely-generated plasma may be used as a cleaning plasma to clean process chamber components between film/layer deposition steps which are carried out in process volume 106. The cleaning plasma may be further excited by the RF power source 122 provided to the showerhead. Suitable plasma source gases used to generate the cleaning plasma may include, by way of example and not of limitation, NF₃, F₂, and SF₆. Examples of remote plasma sources are disclosed in U.S. Pat. No. 5,788,778, issued Aug. 4, 1998 to Shang et al., which is incorporated by reference to the extent not inconsistent with the present disclosure. In one embodiment, chamber 100 may accommodate a substrate 101 with a surface area of 10,000 cm² or more, typically 40,000 cm² or more, and commonly 55,000 cm² or more.

Typically, an apparatus for forming solar cells is configured with multiple chambers. In the past, such multiple chambers were typically in the form of an in-line design, where the chambers were arranged in sequence in a line, one following behind the other. However, our analysis has shown that to make a “three” chamber design economically competitive, it is necessary to use a multi-chamber processing configuration which is not an in-line arrangement.

The described subsequently herein, multiple PECVD processing chambers need to be arranged in a circular pattern around a transfer chamber, where the distance from the transfer chamber to each processing chamber is advantageous. A robot is present in the transfer chamber, which robot transfers substrates back and forth between the multiple PECVD processing chambers. All chambers are in communication with the transfer chamber, including a load lock/docking chamber which initially transfers samples to the transfer chamber.

### Example One

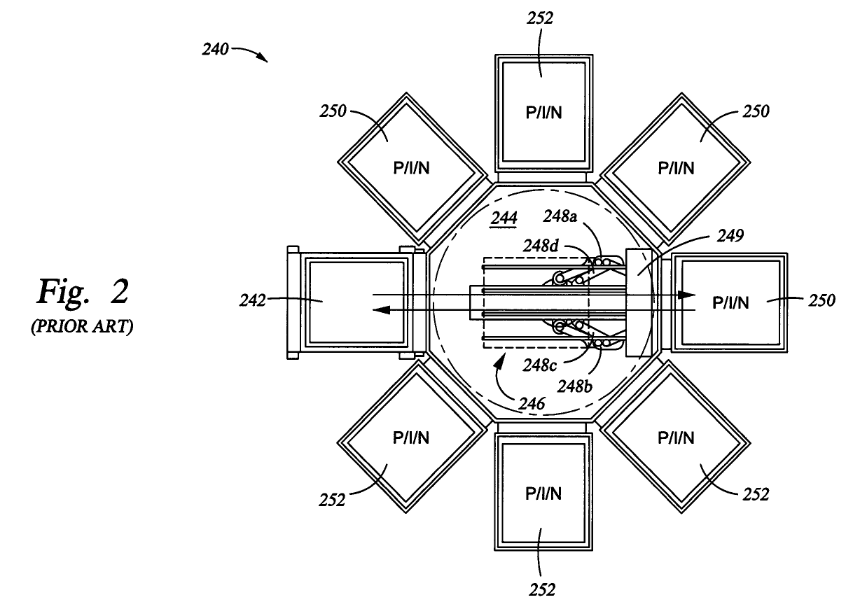

FIG. 2 shows an comparative exemplary “single” chamber process system 240. While a similar processing system could be used to produce a solar cell configuration other than a PIN configuration, for purposes of discussion in general, this layer configuration is described. One of skill in the art can extend the concepts described herein to structures other than those having a PIN configuration.

In a “single” chamber PIN configuration processing method, all of the p, i, and n layers of a PIN solar cell are deposited in a single process chamber. The method includes the following steps: a) providing a single PECVD processing chamber configured to deposit a p-doped layer, an intrinsic layer, and an n-doped layer; b) placing a substrate having a surface area of 1,000,000 mm² or larger within the PECVD processing chamber; c) forming at least one p-doped layer upon the substrate; d) forming at least one intrinsic layer overlying the p-doped layer; and e) forming at least one n-doped layer overlying the intrinsic layer. When it is desired to produce a tandem solar cell, which includes more than one solar cell in a stacked structure, the process may include the additional steps of f) forming at least one second p-doped layer overlying the n-doped layer of step e); g) forming at least one second intrinsic layer overlying the second p-doped layer of step f); and h) forming a second n-doped layer overlying the second intrinsic layer of step g), by way of example and not by way of limitation.

A “single” chamber PECVD cluster processing system 240 of the kind shown in FIG. 2 typically includes a load lock docking chamber 242 and from five to seven film/layer-depositing chambers, each of which is capable of depositing a p-doped layer, an i-layer, and an n-doped layer. The embodiment which is shown in FIG. 2 makes use of seven film/layer depositing chambers. The processing chambers 250 are capable of depositing a-silicon-containing layers, while the processing chambers 252 are capable of depositing mc-silicon-containing layers or amorphous silicon (a-silicon) layers This provides additional processing functionality. A central transfer chamber 244 is in communication with the load lock chamber 242 and with the film/layer deposition chambers 250 and 252. A central substrate transferring robot 246 works within the central processing chamber 244 to move the substrates (not shown) within the cluster processing system 240. The central substrate transferring robot 246 advantageously is a dual armed robot. By a dual armed robot it is meant that there are two sets of robot arms spaced apart which are capable of handling two substrates simultaneously. For example, upper arms 248a and 248b handle a first substrate, while lower arms 248c and 248d handle a second substrate. Use of a dual armed robot makes possible the rapid transfer of a first substrate (not shown) out of a processing chamber 250, for example, followed by the transfer of a second substrate (not shown) into processing chamber 250. This rapid removal of one substrate and insertion of another substrate can be made while an entrance 249 (typically a slit valve) is open, and reduces the number of openings and closings of the entrance to a processing chamber 250. This enables a much more efficient multi-chambered processing operation. A good example of a central substrate handling robot is described in U.S. Published Application No. US 2007/0280816 A1, published Dec. 6, 2007. This document illustrates a dual armed robot in FIG. 1, and describes the robot 110 as being a vacuum robot which is disposed in the transfer chamber to facilitate transfer of a substrate between a load lock chamber and a processing chamber, as well as between processing chambers.

A p-doped layer, by way of example and not by way of limitation, may be doped using a Group III element, such as boron, aluminum, gallium, or indium. The p-doped layer may also be a silicon carbide alloy with amorphous silicon, which alloy may take various forms depending on the silicon carbide content of the p-doped layer. The intrinsic, i-layer is typically silicon and may be a-silicon or mc-silicon, for example. The n-doped layer may doped with a phosphorous-comprising dopant, and is frequently deposited as a dual composition layer, where the first portion of the n-doped layer exhibits a lower hydrogen content than the second part of the n-doped layer.

While the amount of process chamber contamination which occurs during deposition of a p-doped layer is dependent upon the particular dopant material used, there is always some build up of the dopant material on the processing chamber interior and on various processing apparatus surfaces present within the chamber. This build up of dopant material can provide contamination of the composition of a subsequently deposited layer of material, and can be the source of particulates, unless the process chamber interior is cleaned periodically to remove deposition processing residue which accumulates over time. This is why it is necessary to frequently clean the interior of a “single” chamber design cluster processing system of the kind described above.

### Example Two

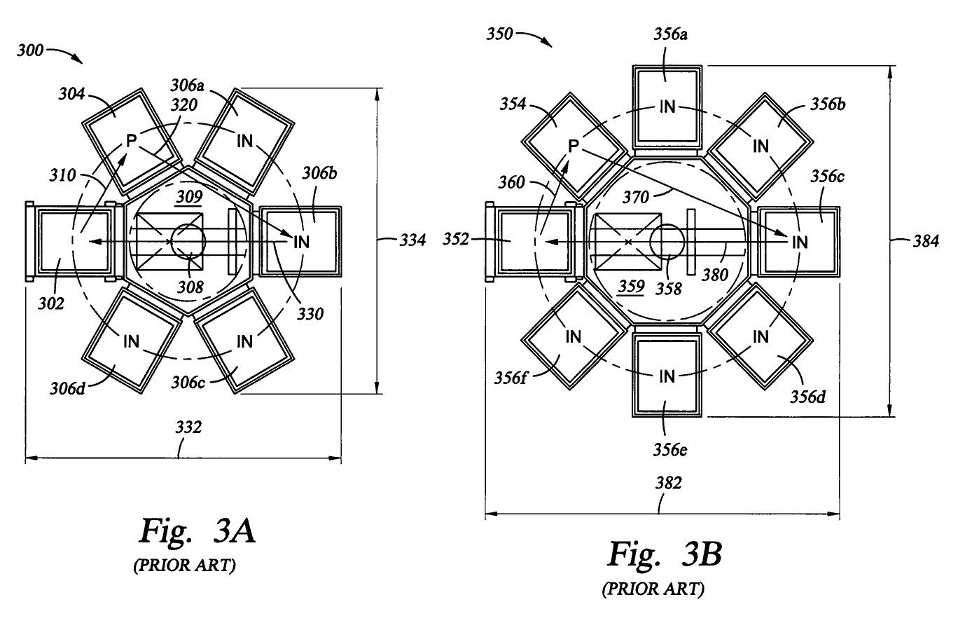

FIG. 3A shows a comparative “two” chamber design PECVD cluster processing system 300. This embodiment includes five processing chambers. The p-doped layer is deposited in one chamber, while the i-layer and n-doped layer are deposited in a single additional chamber. In particular, the processing chamber 304 is capable of depositing the p-doped layer which typically contains amorphous silicon, but which may also contain microcrystalline silicon or polycrystalline silicon. The i-layer and the n-doped layer may be deposited in process chambers 306 a) through 306 d). The length of the distances 332 and 334 illustrated on FIG. 3A are such that the central substrate transfer robot 308 can work more efficiently. The central substrate transfer robot 308 may be a dual armed robot of the kind described with reference to the central substrate transfer robot 246 shown in FIG. 2. An example of a commercially available “two” chamber design, multi-chambered processing system, for processing of solar cells is the model AKT 60K PECVD System which is available from Applied Materials, Inc. of Santa Clara Calif. This “two” chamber design solar cell fabrication system is capable or processing a substrate having a surface area of 5,720,000 mm².

The number of IN processing chambers is typically four or more times greater than the number of P processing chambers because the i-layer deposited in the IN chamber is typically much thicker than the p-doped or n-doped layer and requires a longer deposition time period. To optimize performance of a cluster system 300, the number of P chambers relative to the number of IN chambers can be optimized based on the product which is to be produced in cluster system 300.

The number of times the substrate must be transferred is reduced in view of the ability to deposit the i-layer and the n-doped layer in the same chamber. Arrows 310, 320, and 330, illustrate the general transfer of the substrates in the order transfer occurs only. Arrow 310 indicates that the substrate is first transferred to the process chamber 304 in which the p-doped layer is deposited. Arrow 320 indicates that after deposition of the p-doped layer, the substrate is transferred to a processing chamber 306a, or 306b, or 306c, or 306d, in which the i-layer and the n-doped layer are deposited. Arrow 330 indicates that after deposition of the i-layer and the n-doped layer, the substrate is transferred back to the load-lock chamber 302. As discussed earlier herein, the position of the arrows is not intended to illustrate the direction of travel or the length of the travel distance for a given transfer operation. The arrows are drawn as shown to provide a simpler illustration of the concept. Based on the description previously provided, it is readily apparent that the substrate from load-lock chamber 302 is first transferred to the central transfer chamber 309, and from there to the p-doping chamber 304. Subsequently, the substrate is transferred from the p-doping chamber 304—back to the central transfer chamber 309. The substrate is then transferred to one of the IN process chambers for deposition of the i-layer and n-doped layer. Subsequently the substrate is transferred back to the central transfer chamber 309 for transfer back to the load-lock chamber 302. The central substrate transfer robot Typically there is an additional robot (not shown) to transfer the substrate directly from the load-lock chamber 302 to the p-doped layer processing chamber 304.

While there may be some phosphorous contamination of the IN processing chamber, and this requires periodic cleaning of the IN chambers, the cleaning is less demanding and less critical with respect to device performance than the cleaning for a p-doped processing chamber. Since the cleaning operation, which includes NF₃ plasma cleaning, pumping/purging, and a seasoning process, requires a substantial amount of the total processing time, an average of about 13% of the total processing time for a “single” chamber design multi-chambered processing system; an average of about 13% of the processing time for a “two” chamber design multi-chambered processing system; and an average of about 5% of the time required for a “three” chamber design multi-chambered processing system, it is readily apparent that cleaning time is a very important consideration in the design of the multi-chambered processing system. It is also readily apparent that the reduced cleaning operational time required for the “three” chamber design multi-chambered processing system needs to be factored into a decision of which chamber design is most advantageous. The cleaning operational times provided herein are based on empirical data for the cleaning of various processing chambers using a remotely generated plasma containing reactive fluorine containing species. The cleaning times were determined as a part of the development of the present invention.

The importance of the cleaning operational time, relative to other processing times becomes apparent in the tables which subsequently follow, which show that when a processing chamber has to be cleaned frequently, the cleaning time is determinative of whether it is advantageous to use a “single” chamber processing design, a “two” chamber processing design, or a “three” chamber processing design.

FIG. 3B shows a comparative “two” chamber PECVD cluster processing system 350, which is similar to the two chamber PECVD cluster processing system 300 shown in FIG. 3A, except that there are seven film/layer depositing chambers. One film forming chamber 354 capable of depositing a p-doped layer, and six other film/layer depositing chambers 356a-356f, capable of depositing an i-layer and an n-doped layer. The cluster processing system includes a load lock docking chamber 352, and seven film deposition chambers of the kind shown in FIG. 1, arranged around a transfer chamber 359 which contains a robot 358. The length of the distances 382 and 384 illustrated on FIG. 3B are representative of a solar cell “two” chamber design used in the processing of solar cells on a substrate having a surface area of 5,720,000 mm², which is available from Applied Materials, Inc. as a model number AKT 60K PECVD System.

### Example Three

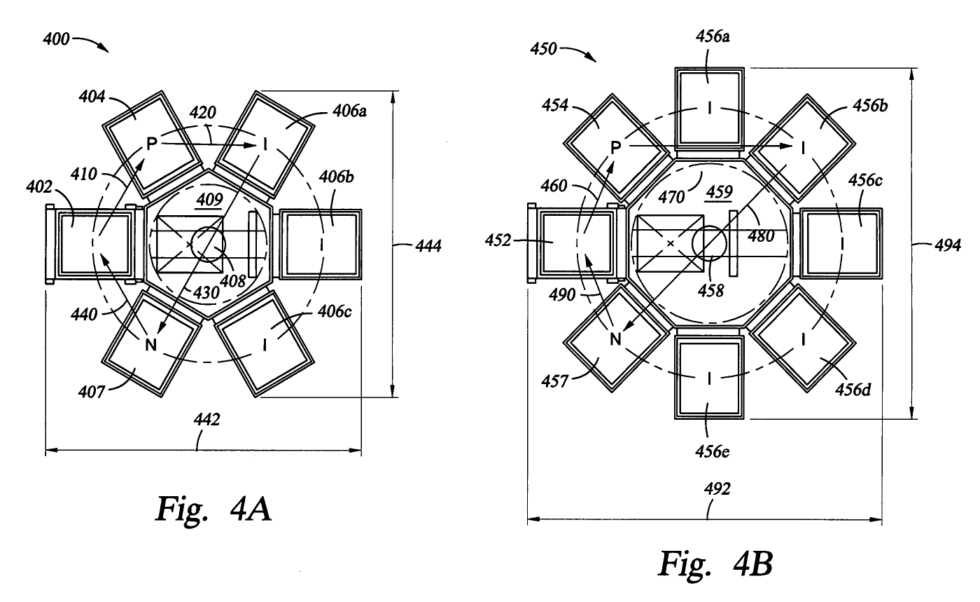

FIG. 4A shows a “three” chamber design of a multi-chamber PECVD cluster processing system 400 of the kind which may be used to practice embodiments of the present invention. This cluster processing system is referred to as a “three” chamber process apparatus because each different kind of layer is deposited in a separate chamber. The three chamber processing system includes a load lock docking chamber 402 and five film/layer-depositing chambers. One film-forming chamber 404 is capable of depositing a p-doped layer; three film-forming chambers 406a-406c, are capable of depositing an i-layer; and one film-forming chamber 407 is capable of depositing an n-doped layer. The cluster processing system includes a load lock docking chamber 402, and five film deposition chambers of the kind shown in FIG. 1, arranged around a transfer chamber 409 which contains a central substrate transfer robot 408. The central substrate transfer robot 408 is advantageously a dual arm transfer robot of the kind described with reference to the FIG. 1 dual arm central substrate transfer robot 246.

Again, the arrows 410, 420, 430, and 440 are representative of the concept of the transfer of the substrates, but do not illustrate the direction or length of travel per each transfer, as explained with reference to FIGS. 3A and 3B. The length of the distances 442 and 444 illustrated on FIG. 4A are representative of a solar cell “three” chamber design used in the processing of solar cells on a substrate having a surface area of 5,720,000 mm², which is available from Applied Materials, Inc. as a model number AKT 60K PECVD System.

FIG. 4B shows a “three” chamber design PECVD cluster processing system 450, which is similar to the “three” chamber design PECVD cluster processing system 400 shown in FIG. 4A, except that there are seven film/layer depositing chambers. One film-forming chamber 454 capable of depositing a p-doped layer; five film/layer depositing chambers 456a-456e, capable of depositing an i-layer; and one film/forming chamber 457 capable of depositing an n-doped layer. The cluster processing system includes a load lock docking chamber 452, and seven film deposition chambers of the kind shown in FIG. 1, arranged around a central transfer chamber 459 which contains a central substrate transfer robot 458, which is advantageously a dual armed robot.

The arrows 460, 470, 480, and 940 are representative of the concept of the transfer of the substrates, but do not illustrate the direction or length of travel per each transfer, as explained with reference to FIG. 4A. The length of the distances 492 and 494 illustrated on FIG. 4B are representative of a solar cell “three” chamber design used in the processing of solar cells on a substrate having a surface area of 5,720,000 mm², as described above.

### Example Four

As is illustrated in the Table which follows, when process chamber cleaning operations required during a commercial fabrication operation make up a substantial amount of the total substrate processing time, it is not practical to use particular multi-chamber processing designs. Prior to the present invention, there was a question as to whether the “one” chamber design, “two” chamber design, or the “three” chamber design was preferable. As previously discussed, it has been assumed that a “two” chamber design is preferable from a manufacturing cost point of view, despite the fact that the device performance for a substrate produced using a “two” chamber design may not be as good long term (due to at least a low level interface contamination for solar cells produced using a “two” chamber design).

However, we have determined, unexpectedly, based on recently acquired cleaning operation requirements, that for the cluster multi-chambered systems of the kind illustrated in FIGS. 3 and 4, the manufacturing cost is slightly less for a “three” chamber design than for a “two” chamber design. This is illustrated by the Table below, with respect to a single junction film stack, where the thickness of the layers and the deposition rate were as follows. A p-doped layer thickness was about 120 Å to about 150 Å, and the deposition rate was about 150 Å/min. An i-layer thickness was about 2500 Å and the deposition rate was about 220 Å/min. An n-doped layer thickness was about 250 Å and the deposition rate was about 250 Å/min. The substrate size in each instance was 5,720,000 mm².

A remotely generated fluorine-species comprising plasma is generally preferred to remove the p-layer dopant from the interior surfaces of the process chamber and included apparatus. Typically the remotely-generated plasma comprises species generated from an NF₃-comprising plasma source gas. Other sources of fluorine active species may also be used. The process chamber in which a p-doped layer is deposited needs cleaning periodically to remove build up of p-doped layer processing residue. To avoid possible contamination of substrates which are processed, the process chamber was cleaned to remove the p-doped layer material residue after the processing of about 50 substrates, where a p-doped layer having a thickness of about 150 Å has been deposited on each substrate. This amount of p-doped layer processing produces an average residue build-up on process chamber surfaces ranging from about 5,000 Å to about 8,500 Å in thickness, and the average cleaning (removal) rate achievable for the p-doped. layer processing residue was about 5,000 Å of thickness/min. The process chamber is cleaned to remove an i-layer processing residue after the processing of about 10 substrates, when an i-layer having a thickness of about 2,000 Å to about 3,000 Å has been deposited on each substrate. This amount of i-layer deposition produces an average residue build-up on process chamber surfaces ranging from about 20,000 Å to about 30,000 Å in thickness. The average cleaning rate achievable for an i-layer deposition chamber was also in the range of about 5,000 Å/min. The process chamber is cleaned to remove an n-doped layer processing residue after the processing of about 50 substrates, when an n-doped layer having a thickness of about 200 Å to about 300 Å has been deposited on each substrate, by way of example. This amount of n-doped layer deposition produces an average residue build-up on process chamber surfaces ranging from about 10,000 Å to about 15,000 Å in thickness. The average cleaning rate for a n-doped layer deposition chamber was also in the range of about 5,000 Å/min. When a “two” chamber design multi-layered processing chamber is used, the requirements for cleaning the chamber where the p-doped material is deposited are the same as described above. The 2 requirements for cleaning an IN chamber, where there is some build-up of i-layer 3 material residue intermixed with build-up of n-doped layer material residue, are such that 4 the process chamber needs cleaning to remove an average of about 2,500 Å to about 3,300 Å of mixed material residue after the deposition of the i-layer and n-doped layer on one substrate. Again, the average cleaning (removal) rate was about 5,000 Å/min.

In addition to the actual cleaning time, the cleaning operation includes pumping/and purging of fluid flow materials, and a seasoning process to recondition each chamber prior to resumption of layer deposition within the chamber. Please see the Table below for the average cleaning operation time per substrate processed, for each different kind of processing chamber.

TABLE
Comparison of “One” Chamber Design, “Two” Chamber Design,
and “Three Chamber Design Processes

| | | | | | Step | | Total | |
|---|---|---|---|---|---|---|---|---|
| | | | | Number | Clean | Total | Clean | |
| | | | Step | Processed | Season | Process | Season | Total |
| | | Chamber | Clean | Substrates | Time | Time | Time | Time |
| | | Process | Season | Before | per | per | per | per |
| Chamber | Process | Time | Time | Cleaning | Substr. | Substr. | Substr | Substr |
| Design | Steps | (sec) | (sec) | Required | (sec) | (sec) | (sec) | (sec) |
| One | PIN | 927 | 140 | 1 | 140 | 927 | 140 | 1067 |
| Chamber | | | | | | | | |
| PIN | | | | | | | | |
| Two | P | 117 | 185 | 50 | 4 | 978 | 141 | 1120 |
| Chamber | IN | 861 | 138 | 1 | 138 | | | |
| P-IN | | | | | | | | |
| Three | P | 117 | 185 | 50 | 4 | 1046 | 55 | 1101 |
| Chamber | I | 799 | 458 | 10 | 46 | | | |
| P-I-N | N | 129 | 278 | 50 | 6 | | | |

As can be seen from the above table, the total processing time per substrate, including layer depositions in combination with cleaning and seasoning time, for a “three” chamber process design is 1101 seconds/substrate. For a “two” chamber design process, the total processing time is 1120 seconds/substrate. For a “one” chamber design process, the total processing time is 1067 seconds/substrate. This was a totally unexpected result, prior to the current empirical work to determine the cleaning and seasoning times required for surfaces upon which particular residues had accumulated. One of skill in the art would certainly not expect that a two chamber design process would require more processing time per substrate than either a one chamber design process or a three chamber design process.

In addition, a calculation of the cost of the cleaning for the “three” chamber design process compared with the cost of the cleaning for the “two” chamber design process has shown that the cost per substrate for the “three” chamber design process is about $4.80 per substrate, while the cost per substrate for the “two” chamber design process is about $5.92 per substrate. This difference in cost is attributable to the need for additional removal of seasoning film when the “two” chamber design process is used. It is necessary to remove the seasoning film as a part of each cleaning cycle. The seasoning film thickness remains the same regardless of the length of the cleaning cycle; so, if it is necessary to clean processing chambers more often, the cost for removal of a seasoning layers is increased. The number of substrates processed prior to need for a cleaning cycle for the “two” chamber process design is 50 with regard to the P processing chamber, but is only 1 substrate with regard to the IN processing chamber. The number of substrates processed prior to need for a cleaning cycle for the three chamber process is 50 with regard to the P processing chamber, is 10 with regard to the I processing chamber, and is 50 with regard to the N processing chamber.

A comparison of the vacuum robot utilization indicates that the mechanical throughput (robot handling capability only) in substrates per hour is not significantly better for a “two” chamber design process than for a “three” chamber design process. This is because, for the “three” chamber design process, a dual arm robot can be used improve the mechanical throughput rate, providing for a “paired transfer” of substrates. However, for a “two” chamber design process, where the IN process chamber has to be cleaned after each film deposition of the i-layer and n-doped layer in the In process chamber, a dual arm robot provides little benefit in terms of overall mechanical throughput time. For the “three” chamber design process using the chamber arrangement shown in FIG. 4B, the mechanical throughput time in substrates per hour was 20. For the “two” chamber design process using the chamber arrangement shown in FIG. 3B, the mechanical throughput time in substrates per hour was 20.6 substrates per hour. However, when the difference in total cleaning time of 10 seconds per substrate in favor of the “three” chamber design process is taken into account, the “two” chamber design process and the “three” chamber design process are very comparable. In fact, a calculation of the maximum total substrate throughput (deposition, cleaning, and substrate handling) per hour is 20 substrates per hour for both the “two” chamber design process and the “three” chamber design process. And, as discussed above, the cleaning cost per substrate is lower by 19% for the “three” chamber design process.

While the invention has been described in detail above with reference to several embodiments, various modifications within the scope and spirit of the invention will be apparent to those of working skill in this technological field. Accordingly, the scope of the invention should be measured by the appended claims.

We claim:

1. A method of fabricating a solar cell-comprising substrate, the method comprising:
a) providing at least one PECVD processing chamber configured to deposit a p-doped layer, at least three PECVD processing chambers configured to deposit an i-layer, and at least one PECVD processing chamber configured to deposit an n-doped layer, wherein each p-doped layer is deposited in a processing chamber configured to deposit a p-doped layer, each i-doped layer is deposited in a processing chamber configured to deposit an i-doped layer, and each n-doped layer is deposited in a processing chamber configured to deposit an n-doped layer;
b) providing a central substrate transferring chamber which is used to transfer substrates between said PECVD processing chambers;
c) providing a substrate transferring robot having at least two sets of arms, where each set of arms is capable of transferring substrates, wherein said substrate transferring robot is located within said central substrate transferring chamber;
d) transferring solar cell substrates having a surface area of at least 1,000,000 mm² from PECVD processing chamber to PECVD processing chamber through said at least one central substrate transferring chamber using said substrate transferring robot;
e) depositing at least one p-doped layer, at least one i-layer, and at least one n-doped layer each solar cell-comprising substrate; and
e) periodically cleaning each of said processing chambers using a fluorine-comprising plasma to remove residue created during said depositing of a layer in said processing chamber.

2. A method in accordance with claim 1, wherein said p-doped layer has a thickness ranging from about 120 Å to about 150 Å, and wherein a PECVD processing chamber in which said p-doped layer is deposited is cleaned when the thickness of residue formed on processing chamber surfaces ranges between about 5,000 Å and about 8,500 Å.

3. A method in accordance with claim 1, wherein said i-layer has a thickness ranging from about 2,000 Å to about 3,000 Å, and wherein a PECVD processing chamber in which said i-layer is deposited is cleaned when the thickness of residue formed on processing chamber surfaces ranges between about 20,000 Å and about 30,000 Å.

4. A method in accordance with claim 1, wherein said n-doped layer has a thickness ranging from about 200 Å to about 300 Å, and wherein a PECVD processing chamber in which said n-doped layer is deposited is cleaned when the thickness of residue formed on processing chamber surfaces ranges between about 10,000 Å and about 15,000 Å.

5. A method in accordance with claim 1, wherein the number of single junction solar cell substrates processed per hour is at least 20.

6. A method in accordance with claim 5, wherein said solar cell substrate comprises a multiple of solar cell junctions, and wherein the number of solar cell substrates produced per hour is equal to the number 20 divided by the number of junctions or a larger number.

7. A method in accordance with claim 1, wherein an average total clean and seasoning time period per substrate, considering the cleaning and seasoning of all PECVD chambers is about 55 seconds or less.

8. An apparatus used to fabricate a solar-cell comprising substrate, the apparatus comprising:
a) at least one PECVD processing chamber configured to deposit a p-doped layer, at least three PECVD processing chambers configured to deposit an i-layer, and at least one PECVD processing chamber configured to deposit an n-doped layer, wherein said PECVD processing chambers are each sized to process a substrate having a surface area of at least 1,000,000 mm²;
b) a central substrate transferring chamber which is used to transfer substrates between said PECVD processing chambers;
c) a substrate transferring robot having at least two sets of arms, where each set of arms is capable of transferring substrates, wherein said substrate transferring robot is located within said central substrate transferring chamber; and
d) an apparatus which provides a source of fluorine-comprising reactive species which is in communication with each of said PECVD processing chambers recited in a).

9. An apparatus in accordance with claim 7, wherein said transfer robot is capable of at least 15 paired transfers of substrates per hour.

10. An apparatus in accordance with claim 8, wherein a mechanical throughput rate of substrates per hour within said apparatus is at least 20.
